(19) United States
(12) Patent Application Publication
(10) Pub. No.: US 2013/0309807 A1
(43) Pub. Date: Nov. 21, 2013

(54) PATTERN FORMING METHOD AND MANUFACTURING METHOD OF SOLAR BATTERY

(71) Applicants: Yoshinobu Hirokado, Tokyo (JP); Shiro Sekino, Tokyo (JP)

(72) Inventors: Yoshinobu Hirokado, Tokyo (JP); Shiro Sekino, Tokyo (JP)

(73) Assignee: Mitsubishi Electric Corporation, Tokyo (JP)

(21) Appl. No.: 13/977,744

(22) PCT Filed: Jun. 8, 2011
(86) PCT No.: PCT/JP2011/063136

§ 371 Date: Jul. 1, 2013

(30) Foreign Application Priority Data
Feb. 4, 2011 (JP) 2011-023166

(51) Int. Cl. H01L 31/0224

(52) U.S. Cl. CPC H01L 31/022425
USPC 438/98

(57) ABSTRACT

A pattern forming method of forming a pattern by printing a pattern formation paste containing a pattern forming material and a binder component on a substrate having irregularities on a surface includes a foundation-layer forming step of forming a foundation layer by printing a foundation layer paste containing a same binder component as the binder component contained in the pattern formation paste on the surface of the substrate by the screen printing method in such a manner as to cover the irregularities with the foundation layer paste, and a paste-pattern forming step of forming a pattern of the paste by printing the pattern formation paste on the foundation layer by the screen printing method.

### FIELD

The present invention relates to a pattern forming method and a manufacturing method of a solar battery, and more particularly to a pattern forming method and a manufacturing method of a solar battery capable of forming thick-film patterns on a surface of a substrate having irregularities by using screen printing.

### BACKGROUND

Conventionally, as a technique of forming thick-film patterns, the following method has been proposed. In an oil-repellant film forming process, an oil repellant film at a larger contact angle with respect to a thick-film conductive paste than that of one surface of a substrate and made of fluororesin or the like is formed on the surface of the substrate. In a subsequent printing process, the thick-film conductive paste is thick-film-screen printed on the oil repellant film, thereby forming a printed film. Furthermore, in a burning process, the substrate on which the printed film is formed is burned, thereby generating thick-film conductors from the printed film and, at the same time, an oil repellent film is decomposed and removed (see, for example, Patent Literature 1).

Furthermore, as another thick-film pattern forming method, there has been proposed a method such that a foundation layer made of an organic polymer compound is formed on a glass substrate, a paste that becomes either an electrode or a barrier is printed into a pattern by screen printing, and the foundation layer is burned down in a subsequent burning process (see, for example, Patent Literature 2).

### CITATION LIST

### Patent Literatures

Patent Literature 1: Japanese Patent Application Laid-open No. 2000-208899
Patent Literature 2: Japanese Patent Application Laid-open No. H6-150812

### SUMMARY

### Technical Problem

However, according to such conventional techniques, the foundation layer that is burned down in a burning process is formed before thick-film pattern printing on an assumption that the surface on which the thick-film patterns are formed is substantially flat. Accordingly, before the thick-film pattern printing, the foundation layer is formed thin in a thickness range from 0.001 micrometer to 5 micrometers.

As a result, in a case of forming a foundation layer on a surface of a workpiece substrate having irregularities having a difference in height of 10 micrometers to 15 micrometers, for example, surface irregularities deriving from the workpiece substrate remain on the surface of the foundation layer. At a time of printing a thick-film paste, a gap is generated between a printing mask and the surface of the workpiece substrate because of the presence of the irregularities on the surface of the foundation layer. Therefore, there is a problem that the thick-film paste enters the gap, thereby generating smears on the thick-film patterns.

Furthermore, according to the conventional techniques, because of the use of screen printing, a urethane rubber called “squeegee” presses (applies a printing pressure on) a surface of a screen mask to press the screen mask against the workpiece substrate, and the squeegee is moved while deforming the screen mask. In this way, the paste is pushed into an opening of the screen mask while contacting an emulsion surface that is a rear surface of the screen mask with the workpiece surface, thereby printing desired patterns on the workpiece substrate.

However, the conventional techniques have the following problems. That is, when the workpiece substrate is thin, for example thinner than 1 millimeter, it is impossible to increase the printing pressure (a squeegee pressure) because of the fragility of the workpiece substrate, and it is impossible to closely attach the emulsion surface that is the rear surface of the screen mask to the workpiece substrate. As a result, smears tend to be generated on the thick-film patterns printed on the workpiece substrate.

The present invention has been achieved to solve the above problems, and an object of the present invention is to provide a pattern forming method and a manufacturing method of a solar battery capable of forming patterns on a thin substrate having irregularities on a surface in a stable state with fewer pattern smears.

### Solution to Problem

In order to solve the above problem and in order to attain the above object, in a pattern forming method of forming a pattern by printing a pattern formation paste containing a pattern forming material and a binder component on a substrate having irregularities on a surface by a screen printing method, the pattern forming method of the present invention includes: a foundation-layer forming step of forming a foundation layer by printing a foundation layer paste containing a same binder component as the binder component contained in the pattern formation paste on the surface of the substrate by the screen printing method in such a manner as to cover the irregularities with the foundation layer paste; and a paste-pattern forming step of forming a pattern of the paste by printing the pattern formation paste on the foundation layer by the screen printing method.

### Advantageous Effects of Invention

According to the present invention, it is possible to form patterns on a thin substrate having irregularities on a surface in a stable state with fewer pattern smears.

### BRIEF DESCRIPTION OF DRAWINGS

FIG. 1 are cross-sectional views schematically depicting respective processes in a pattern forming method according to a first embodiment of the present invention.

FIG. 2 is a characteristic diagram of a cross-sectional shape of a foundation layer (a dried film) formed on a substantially flat substrate by a screen printing method using a foundation layer paste obtained by dissolving a resin in a solvent (BCA).

FIG. 3 is a characteristic diagram of a cross-sectional shape of a foundation layer (a dried layer) formed on a substantially flat substrate by a screen printing method using a foundation layer paste obtained by dissolving a resin in a solvent (Texanol).

FIG. 4 is a characteristic diagram of a cross-sectional shape of a foundation layer (a dried layer) formed on a substantially flat substrate by a screen printing method using a foundation layer paste obtained by dissolving a resin in a solvent (terpineol).

FIG. 5 is a characteristic diagram of a formation size (a width) after printing and drying conductive paste patterns formed on a substantially flat substrate by a screen printing method with respect to a mask size (an opening width size).

FIG. 6 is a characteristic diagram of a formation size (a width) after printing and drying conductive paste patterns formed on a foundation layer formed on a substantially flat substrate using the same resin and the same solvent as those contained in conductive patterns as binder components by a screen printing method with respect to a mask size (an opening width size).

FIG. 7 is a characteristic diagram of a formation size (a width) after printing and drying conductive paste patterns formed on a foundation layer formed on a substantially flat substrate using a resin and a solvent different from those contained in conductive patterns as binder components by a screen printing method with respect to a mask size (an opening width size).

FIG. 8 is a characteristic diagram of an average cross-sectional shape of thick-film patterns formed directly on a substrate having irregularities thinner than 0.5 millimeter by using a mask having a mask size (an opening width size) of 0.05 millimeter.

FIG. 9 is a characteristic diagram of an average cross-sectional shape of thick-film patterns formed on a thin foundation layer that is formed on a substrate having irregularities thinner than 0.5 millimeter by using a mask having a mask size (an opening width size) of 0.05 millimeter.

FIG. 10 is a characteristic diagram of an average cross-sectional shape of thick-film patterns formed on a foundation layer that has a standard thickness and that is formed on a substrate having irregularities thinner than 0.5 millimeter by using a mask having a mask size (an opening width size) of 0.05 millimeter.

FIG. 11 is a characteristic diagram of an average cross-sectional shape of thick-film patterns formed directly on a substrate having irregularities thinner than 0.5 millimeter by using a mask having a mask size (an opening width size) of 0.07 millimeter.

FIG. 12 is a characteristic diagram of an average cross-sectional shape of thick-film patterns formed on a thin foundation layer that is formed on a substrate having irregularities thinner than 0.5 millimeter by using a mask having a mask size (an opening width size) of 0.07 millimeter.

FIG. 13 is a characteristic diagram of an average cross-sectional shape of thick-film patterns formed on a foundation layer that has a standard thickness and that is formed on a substrate having irregularities thinner than 0.5 millimeter by using a mask having a mask size (an opening width size) of 0.07 millimeter.

FIG. 14 is a characteristic diagram of an average cross-sectional shape of thick-film patterns formed directly on a substrate having irregularities thinner than 0.5 millimeter by using a mask having a mask size (an opening width size) of 0.10 millimeter.

FIG. 15 is a characteristic diagram of an average cross-sectional shape of thick-film patterns formed on a thin foundation layer that is formed on a substrate having irregularities thinner than 0.5 millimeter by using a mask having a mask size (an opening width size) of 0.10 millimeter.

FIG. 16 is a characteristic diagram of an average cross-sectional shape of thick-film patterns formed on a foundation layer that has a standard thickness and that is formed on a substrate having irregularities thinner than 0.5 millimeter by using a mask having a mask size (an opening width size) of 0.10 millimeter.

FIG. 17 is a characteristic diagram of a pattern width of thick-film conductive patterns formed on a foundation layer that is formed on a substrate having thinner irregularities than 0.5 millimeter while changing thicknesses by a screen printing method while changing a mask size from 0.05 millimeter to 0.10 millimeter after printing and drying.

FIG. 18-1 is a cross-sectional view of a solar battery, electrode patterns of which are produced by the pattern formation method according to the first embodiment of the present invention.

FIG. 18-2 is a top view of the solar battery, electrode patterns of which are produced by the pattern formation method according to the first embodiment of the present invention.

FIG. 19 are cross-sectional views schematically depicting respective processes in a pattern forming method according to a second embodiment of the present invention.

FIG. 20 are cross-sectional views schematically depicting respective processes in a pattern forming method according to a third embodiment of the present invention.

FIG. 21 is a plan view of relevant parts schematically depicting a state where, in the pattern forming method according to the third embodiment, foundation layers and conductive paste patterns are formed on a surface of a substrate.

### DESCRIPTION OF EMBODIMENTS

Exemplary embodiments of a pattern forming method and a manufacturing method of a solar battery according to the present invention will be explained below in detail with reference to the accompanying drawings. The present invention is not limited to the following descriptions and can be modified as appropriate without departing from the scope of the invention. In addition, in the drawings explained below, for easier understanding, scales of respective members may be different from those of actual products. The same holds true for the relationships between respective drawings. Furthermore, even if the drawings are plan views, hatchings may be added for clearer viewing of the drawings.

### First Embodiment

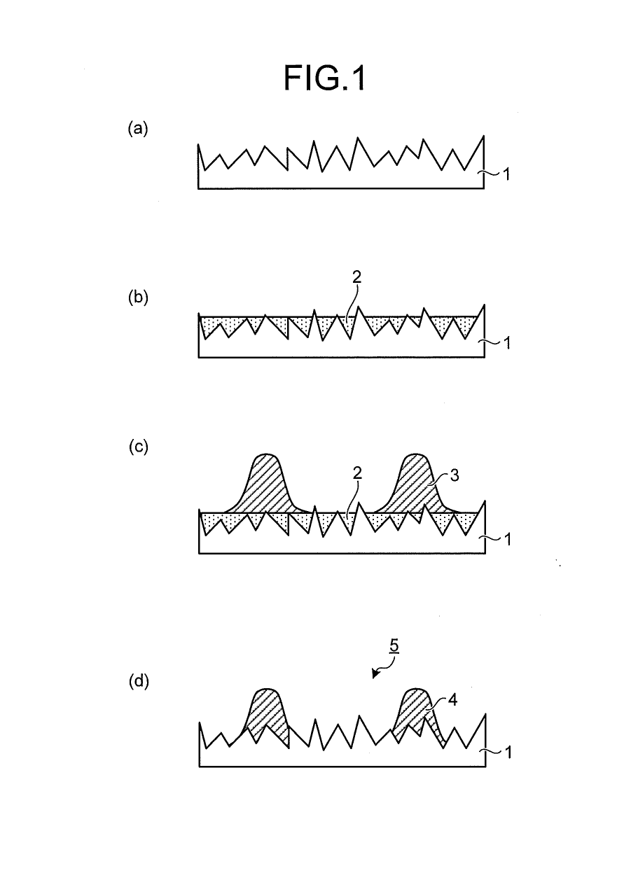

FIG. 1 are cross-sectional views schematically depicting respective processes in a pattern forming method according to a first embodiment of the present invention. The pattern forming method according to the first embodiment is explained below with reference to FIG. 1. First, a substrate 1 having irregularities on a surface is prepared and arranged while turning up a surface having the irregularities (FIG. 1(a)).

Next, a foundation layer paste material (hereinafter, “foundation layer paste”) that becomes a foundation layer material is printed on the irregular surface of the substrate 1 by a screen printing method and the printed foundation layer paste is dried, thereby forming a foundation layer 2 (FIG. 1(b)). By forming the foundation layer 2 on the irregular surface of the substrate 1 and thereby allowing the foundation layer 2 to relax the irregularities on the surface of the substrate 1, the surface of the substrate 1 is made into a substantially flat state. The foundation layer paste is a paste material containing the same binder components as those contained in a conductive paste material (hereinafter, “conductive paste”) that becomes a material of conductive patterns to be printed in a next process. Preferably, a thickness of the foundation layer 2 is set to a thickness at which the foundation layer 2 can relax the irregularities on the surface of the substrate 1 to some extent. For example, if the irregularities on the surface of the substrate 1 have a difference in height of 10 micrometers to 15 micrometers, the foundation layer 2 having the thickness as small as about 0.001 micrometer to 5 micrometers similarly to conventional techniques is incapable of relaxing the irregularities on the surface of the substrate 1.

Next, the conductive paste that becomes the material of the conductive patterns is printed on the foundation layer 2 by the screen printing method and the printed conductive paste is dried, thereby forming conductive paste patterns 3 (FIG. 1(c)). When the substrate 1 is thin, the substrate 1 is fragile. Accordingly, when a printing pressure applied at times of printing the foundation layer paste and the conductive paste is set to be higher than 0.20 (MPA), the substrate 1 is damaged. Therefore, the foundation layer paste or the conductive paste is printed at a low printing pressure (a squeegee pressure) of 0.16 to 0.18 (MPA), for example.

The substrate 1 is burned under conditions of burning down the foundation layer 2, the foundation layer 2 is burned down, and the conductive paste patterns 3 are burned. Burned conductive patterns 4 then contact the substrate 1 and are fixedly and tightly attached to the substrate 1, and a substrate 5 with conductive patterns is completed (FIG. 1(d)).

In the pattern forming method according to the first embodiment described above, the foundation layer 2 is formed on the surface of the substrate 1 in such a manner as to cover the irregular surface of the substrate 1 with the foundation layer 2 by a screen printing method using the foundation layer paste containing the same binder components as those contained in the conductive paste.

In this way, the foundation layer 2 having a predetermined thickness at which the foundation layer 2 can relax the irregularities on the surface of the substrate 1 is formed on the surface of the substrate 1 in advance. Accordingly, the present embodiment can exhibit the following remarkable effects that are not available in conventional techniques. It is possible to form the conductive patterns 4 of a stable shape without any increase in a formation width while suppressing smears derived from the irregularities on the surface of the substrate 1 from being generated on the conductive paste patterns 3 at the time of printing the conductive paste. That is, it is possible to form the conductive patterns 4 of the stable shape without any increase in the formation width while suppressing the conductive paste from entering a gap between a printing mask and the printed surface and smears from being generated on the conductive paste patterns 3. This effect is particularly effective when forming the thick-film conductive patterns 4 and it is possible to obtain the thick-film conductive patterns 4 with fewer smears.

The foundation layer paste contains the same binder components as those contained in the conductive paste. Accordingly, the foundation layer 2 fits well with the conductive paste at the time of printing the conductive paste, and the conductive paste patterns 3 can be printed at a low squeegee pressure. Accordingly, even with the thin substrate 1 the thickness of which is smaller than 1 millimeter, the conductive patterns 4 can be formed without damaging the substrate 1.

A result of verifying the pattern forming method according to the first embodiment is explained next. Foundation layer pastes that became the materials of the foundation layers were formed by a screen printing method each using a printing mask (325 meshes and a total width of 80 micrometers). For comparing states of the foundation layers, a substrate having a substantially flat surface was used. Three types of foundation layer pastes were produced while changing solvents with a resin amount fixed to 10 wt % so as to adjust a viscosity to a screen printable viscosity. As the solvents for the foundation layer pastes, three types of solvents, that is, Texanol, Butyl Carbitol Acetate (BCA), and terpineol were used.

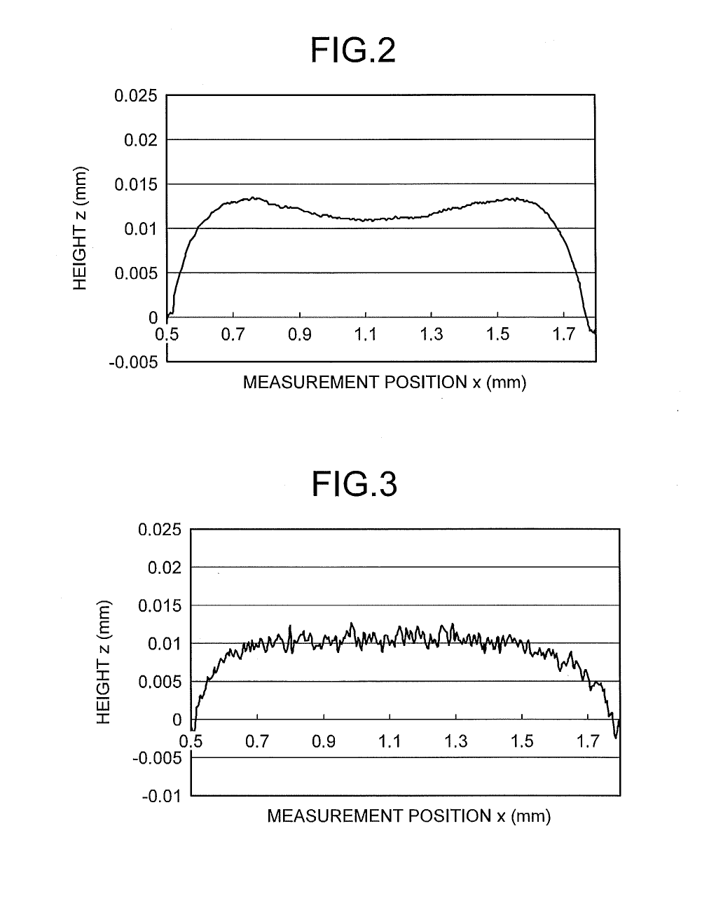

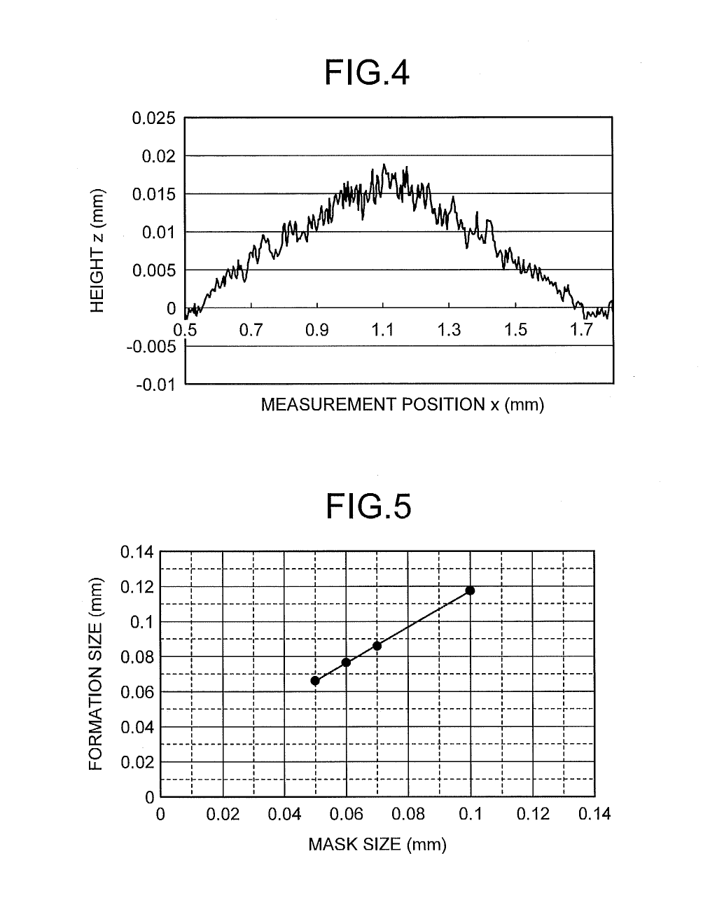

After printing the three types of foundation layer pastes on the substrate by the screen printing method, the printed foundation layer pastes were dried under conditions of holding the printed foundation layers at 90° C. for 15 minutes, thereby forming foundation layers. FIGS. 2, 3, and 4 depict cross-sectional shapes of the foundation layers after printing and drying. FIG. 2 is a characteristic diagram of a cross-sectional shape of a foundation layer (a dried film) formed on a substantially flat substrate by a screen printing method using a foundation layer paste obtained by dissolving a resin in a solvent (BCA). FIG. 3 is a characteristic diagram of a cross-sectional shape of a foundation layer (a dried layer) formed on a substantially flat substrate by a screen printing method using a foundation layer paste obtained by dissolving a resin in a solvent (Texanol). FIG. 4 is a characteristic diagram of a cross-sectional shape of a foundation layer (a dried layer) formed on a substantially flat substrate by a screen printing method using a foundation layer paste obtained by dissolving a resin in a solvent (terpineol).

In FIGS. 2 to 4, a measurement position x (millimeters) on a horizontal axis indicates a position in one direction of an in-plane of the foundation layer (a measurement direction). Furthermore, in FIGS. 2 to 4, a height z (millimeters) on a vertical axis indicates a height of the foundation layer. As shown in FIGS. 2 to 4, thicknesses of the dried foundation layers were 0.01 millimeter to 0.02 millimeter. As shown in FIGS. 2 to 4, differences in the surface roughness were recognized among the foundation layers depending on the used foundation layer pastes. That is, it is understood that the surface roughness of the foundation layers is higher in an order of the foundation layer (see FIG. 2) produced using BCA as the solvent, the foundation layer (see FIG. 3) produced using terpineol as the solvent, and the foundation layer (see FIG. 4) produced using Texanol as the solvent.

Next, the above three types of foundation layers were formed on a plurality of substrates, respectively. Conductive Ag pastes containing silver (Ag) were printed on these foundation layers, respectively by a screen printing method and dried, thereby forming conductive paste pattern samples. As the conductive Ag pastes, two types of pastes, that is, a paste A containing the same resin and the same solvent as those contained in the foundation layer paste for forming each of the foundation layers, and a paste B containing a resin and a solvent different from those contained in the foundation layer paste for forming each of the foundation layers were prepared.

As a screen mask used for screen-printing the conductive Ag pastes, a mask having an opening pattern in which line patterns at a length of 150 millimeters and a line width changed from 0.05 millimeter to 0.1 millimeter were regularly aligned at an interval of 2 millimeters to 3 millimeters was used.

FIGS. 5, 6, and 7 depict representative results of results of measuring a width of the dried conductive paste pattern for each of these conductive paste pattern samples. FIG. 5 is a characteristic diagram of a formation size (a width) after printing and drying conductive paste patterns formed on a substantially flat substrate by a screen printing method with respect to a mask size (an opening width size). That is, FIG. 5 depicts a sample without any foundation layer.

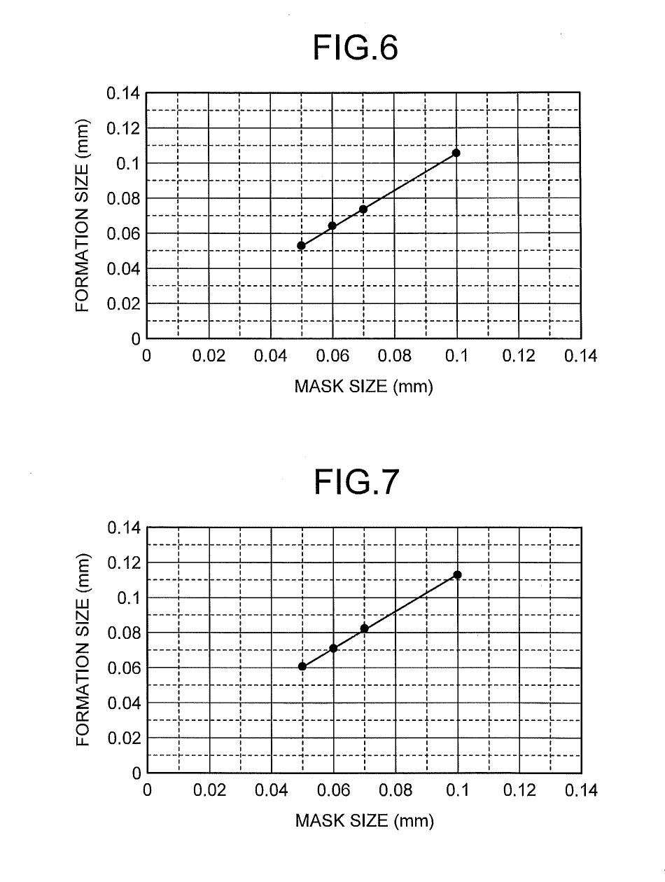

FIG. 6 is a characteristic diagram of a formation size (a width) after printing and drying conductive paste patterns formed on a foundation layer formed on a substantially flat substrate using the same resin and the same solvent as those contained in conductive patterns as binder components by a screen printing method with respect to a mask size (an opening width size). That is, FIG. 6 depicts a sample produced on a foundation layer having a high surface roughness and produced using terpineol as the solvent by the paste A that used the same resin and the same solvent (terpineol) as those contained in the foundation layer.

FIG. 7 is a characteristic diagram of a formation size (a width) after printing and drying conductive paste patterns formed on a foundation layer formed on a substantially flat substrate using a resin and a solvent different from those contained in conductive patterns as binder components by a screen printing method with respect to a mask size (an opening width size). That is, FIG. 7 depicts a sample produced on a foundation layer having a low surface roughness and produced using Texanol as the solvent by the paste B that used the resin and the solvent (BA) different from those contained in the foundation layer.

By comparing FIGS. 5, 6, and 7, differences were recognized among the widths of the dried conductive paste patterns depending on the difference in forming conditions for the conductive paste patterns. That is, the differences were recognized among the widths of the dried conductive paste patterns depending on the difference in the surface roughness of the foundation layer and the type of the conductive paste.

In a case of the sample a foundation layer of which had a high surface roughness and that was produced by the paste A that used the same resin and the same solvent as those contained in the foundation layer (see FIG. 6), smears on the conductive patterns were suppressed and an increase in the width of the dried conductive paste patterns with respect to the pattern opening width of the mask was suppressed (see FIG. 6). On the other hand, in a case of the sample a foundation layer of which had a low surface roughness and that was produced by the paste B that used the resin and the solvent different from those contained in the foundation layer, smears on the conductive paste patterns were not reduced (see FIG. 7).

Next, effects of forming thick-film conductive paste patterns (thick-film paste patterns) on surfaces having irregularities of substrates by the pattern forming method according to the first embodiment were verified. Using appropriate combinations for the suppression of smears on the patterns, thick-film paste patterns were formed on the substrates the surface irregularities of which were about 0.005 millimeter to 0.020 millimeter and thicknesses of which were less than about 0.5 millimeter.

The foundation layer paste was produced by dissolving the resin contained in the conductive paste in the solvent (terpineol). As a foundation-layer printing mask, the same printing mask (325 meshes and a total width of 80 micrometers) as described above was used. As a conductive-paste printing mask, a printing mask having 200 to 300 meshes and a total width of 80 micrometers was used. As the conductive-paste printing mask, printing masks having three types of mask sizes (opening width sizes) of 0.05 millimeter, 0.07 millimeter, and 0.10 millimeter were used.

A plurality of foundation layers changing thicknesses after being dried were produced, and the thicknesses of the foundation layers at which the effect of suppressing smears on the conductive paste patterns were recognized were examined. The thicknesses of the foundation layers were adjusted by repeating printing and drying while fixing the weight percentage of the resin component contained in each foundation layer paste (to 5 wt % to 10 wt %).

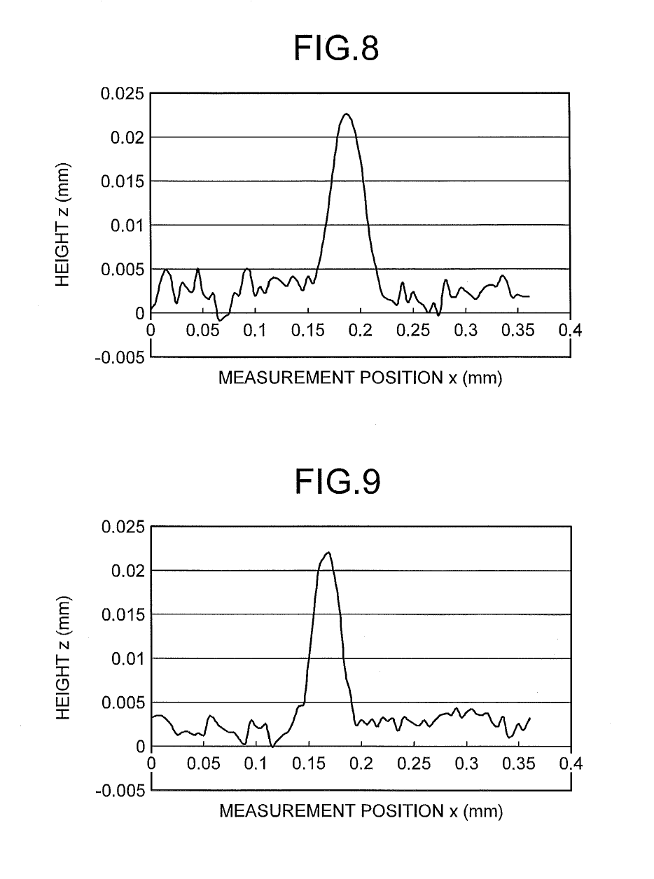

FIGS. 8 to 16 depict average cross-sectional shapes of the conductive paste patterns formed on either the surfaces of the substrates or the foundation layers formed by changing the thicknesses after printing and drying.

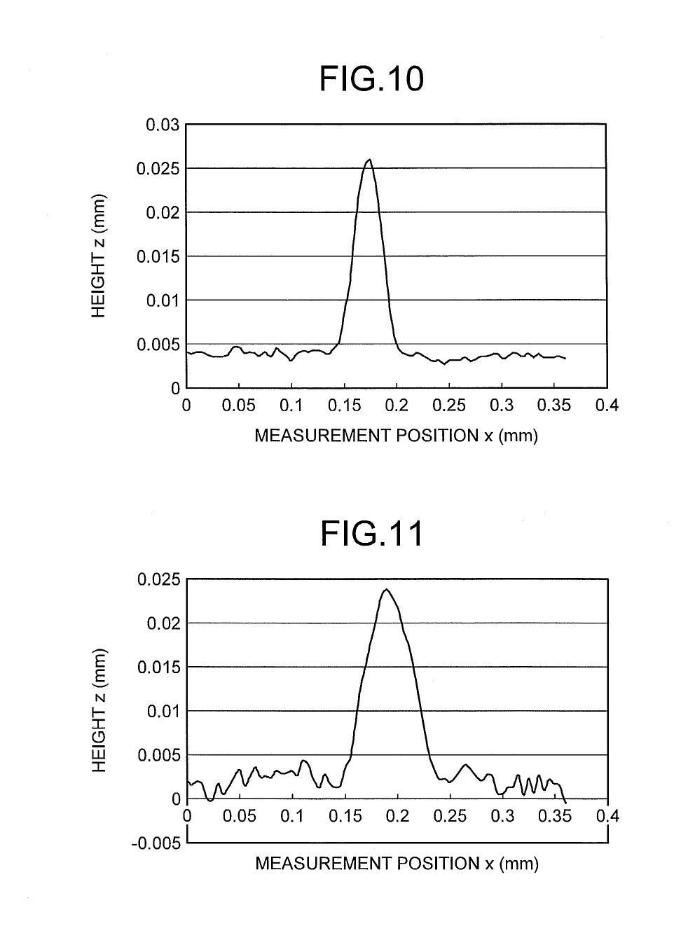

FIG. 8 depicts a comparison and is a characteristic diagram of an average cross-sectional shape of thick-film patterns formed directly on a substrate having irregularities thinner than 0.5 millimeter by using a mask having a mask size (an opening width size) of 0.05 millimeter. FIG. 9 is a characteristic diagram of an average cross-sectional shape of thick-film patterns formed on a thin foundation layer that is formed on a substrate having irregularities thinner than 0.5 millimeter by using a mask having a mask size (an opening width size) of 0.05 millimeter. FIG. 10 is a characteristic diagram of an average cross-sectional shape of thick-film patterns formed on a foundation layer that has a standard thickness and that is formed on a substrate having irregularities thinner than 0.5 millimeter by using a mask having a mask size (an opening width size) of 0.05 millimeter.

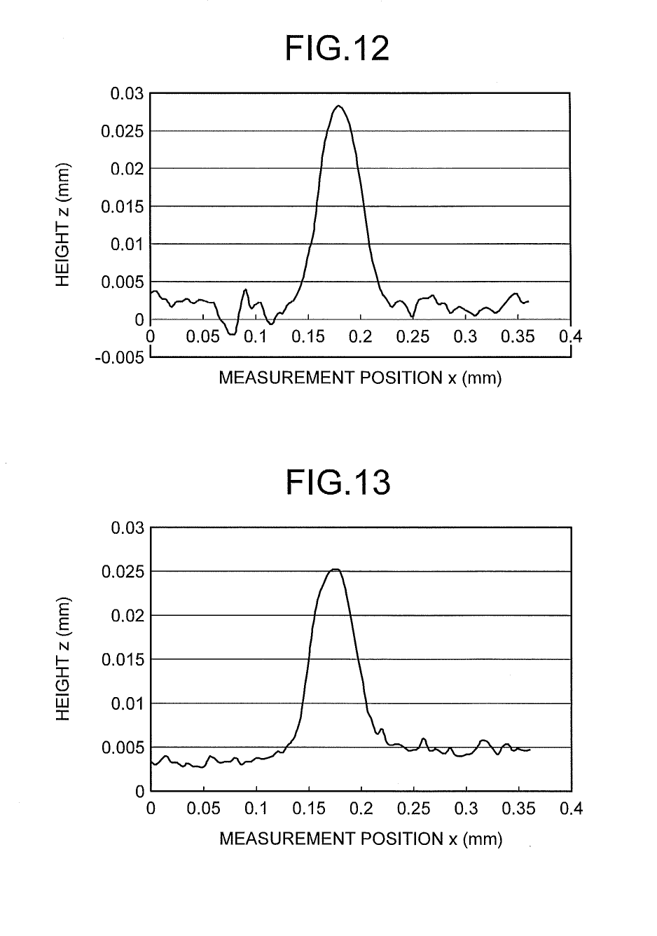

FIG. 11 depicts a comparison and is a characteristic diagram of an average cross-sectional shape of thick-film patterns formed directly on a substrate having irregularities thinner than 0.5 millimeter by using a mask having a mask size (an opening width size) of 0.07 millimeter. FIG. 12 is a characteristic diagram of an average cross-sectional shape of thick-film patterns formed on a thin foundation layer that is formed on a substrate having irregularities thinner than 0.5 millimeter by using a mask having a mask size (an opening width size) of 0.07 millimeter. FIG. 13 is a characteristic diagram of an average cross-sectional shape of thick-film patterns formed on a foundation layer that has a standard thickness and that is formed on a substrate having irregularities thinner than 0.5 millimeter by using a mask having a mask size (an opening width size) of 0.07 millimeter.

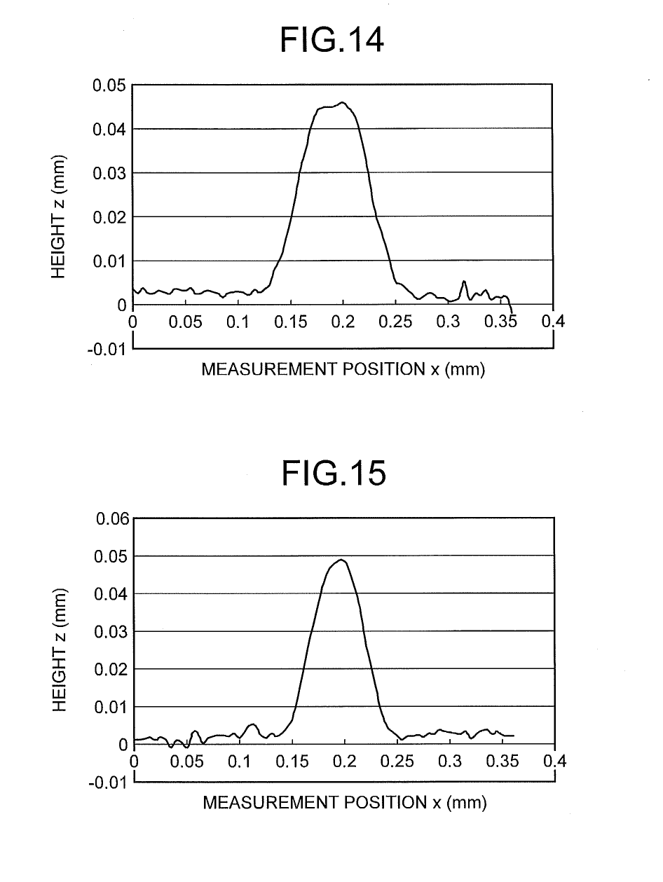

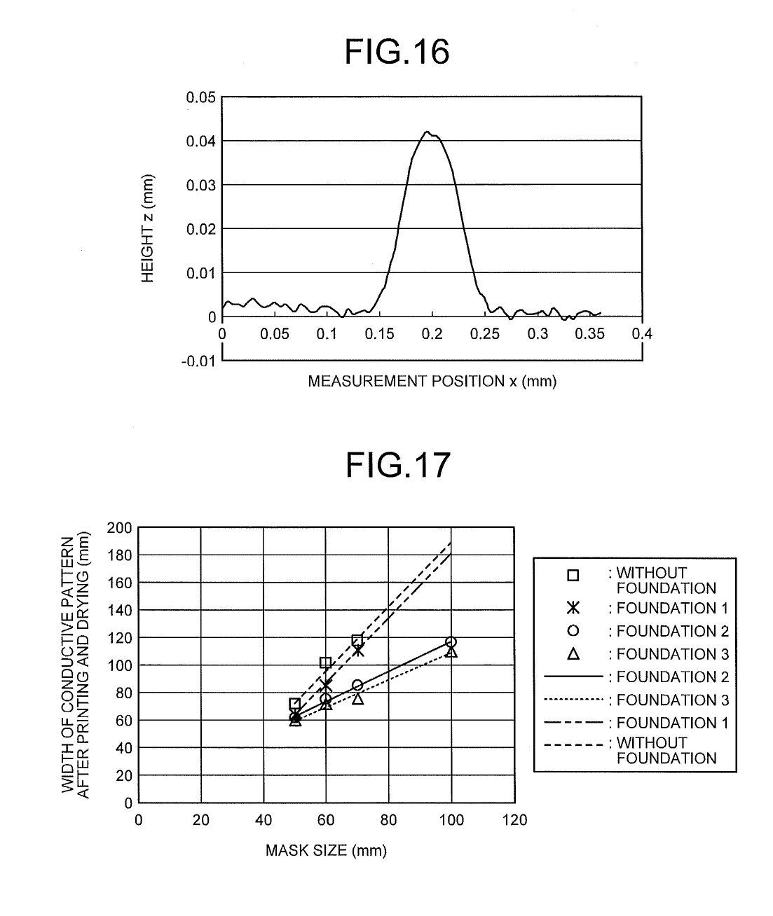

FIG. 14 depicts a comparison and is a characteristic diagram of an average cross-sectional shape of thick-film patterns formed directly on a substrate having irregularities thinner than 0.5 millimeter by using a mask having a mask size (an opening width size) of 0.10 millimeter. FIG. 15 is a characteristic diagram of an average cross-sectional shape of thick-film patterns formed on a thin foundation layer that is formed on a substrate having irregularities thinner than 0.5 millimeter by using a mask having a mask size (an opening width size) of 0.10 millimeter. FIG. 16 is a characteristic diagram of an average cross-sectional shape of thick-film patterns formed on a foundation layer that has a standard thickness and that is formed on a substrate having irregularities thinner than 0.5 millimeter by using a mask having a mask size (an opening width size) of 0.10 millimeter.

The thickness of “thin foundation layer” is a small thickness with respect to the irregularities on a substrate. The thickness of “foundation layer that has a standard thickness” is a thickness suited for irregularities on a substrate. Furthermore, in FIGS. 8 to 14, a horizontal axis indicates the measurement position x (millimeters) in the width direction of the thick-film patterns, and a vertical axis indicates the height z (millimeters) of the thick-film patterns. The cross-sectional shape of each of the conductive paste patterns was measured by repeating a scanning process for scanning the surface of the formed conductive paste pattern in the width direction of the thick-film pattern by a non-contact laser displacement gauge 20 times at a constant pitch (0.025 millimeter) in a length direction of the thick-film pattern.

In FIGS. 8 to 14, the shapes of the surface irregularities (formation surface irregularities) on the used substrates can be confirmed from the measurement results in cases where the foundation layers were not formed (FIGS. 8, 11, and 14). Furthermore, by comparing FIGS. 8 to 10, it can be understood that the formation surface irregularities on the thick-film-pattern formation surfaces were relaxed by increasing the thicknesses of the foundation layers in the case of using the mask having the mask size (the opening width size) of 0.05 millimeter. By comparing FIGS. 11 to 13, it can be understood that the formation surface irregularities on the thick-film-pattern formation surfaces were relaxed by increasing the thicknesses of the foundation layers in the case of using the mask having the mask size (the opening width size) of 0.07 millimeter. By comparing FIGS. 14 to 16, it can be understood that the formation surface irregularities on the thick-film-pattern formation surfaces were relaxed by increasing the thicknesses of the foundation layers in the case of using the mask having the mask size (the opening width size) of 0.10 millimeter.

Table 1 shows ranges of the foundation layer thickness (millimeters) and the surface irregularities on the thick-film-pattern formation surface for each of the above samples. The surface irregularities (formation surface irregularities) on each thick-film-pattern formation surface is defined by a difference between maximum and minimum heights of the surface on which the thick-film patterns are formed, and a result was obtained by measuring the surface irregularities in 20 portions while changing measurement positions on each thick-film-pattern formation surface.

Furthermore, besides these samples, thick foundation layers were formed on the substrates having the irregularities thinner than 0.5 millimeter, respectively, and the thick film patterns were formed on the thick foundation layers by using the masks of 0.05 millimeter, 0.07 millimeter, and 0.10 millimeter, respectively, similarly to the above samples.

TABLE 1

| | | Formation surface |
|---|---|---|
| | Foundation layer | irregularities |
| | thickness (mm) | (mm) |
| Without foundation | 0 | 0.005 to 0.021 |
| layer | | |
| Thin foundation | 0.002 to 0.005 | 0.003 to 0.017 |
| layer | | |
| Standard | 0.006 to 0.010 | 0.002 to 0.011 |
| foundation layer | | |
| Thick foundation | 0.007 to 0.016 | 0.004 to 0.012 |
| layer | | |

As shown in Table 1, the surface irregularities (formation surface irregularities) on the used substrate were 0.005 millimeter to 0.021 millimeter. Furthermore, as is obvious from FIGS. 8 to 14 and Table 1, an increase in the pattern width of the thick-film patterns was suppressed and pattern smears were reduced depending on the difference in the thickness of the foundation layer. That is, it can be understood that the effect of suppressing the increase in the pattern width of the thick-film patterns can be obtained by forming the foundation layer having the thickness in the range from 0.006 millimeter to 0.010 millimeter on the substrate having thinner irregularities than 0.5 millimeter and forming the thick-film pattern on the foundation layer. It was also confirmed that the foundation layer as thin as about 0.002 millimeter to 0.005 millimeter was not effective for suppressing the pattern smears in the case of the surface irregularities on the substrate at this level.

Next, FIG. 17 depicts a result of forming thick-film conductive patterns (thick-film paste patterns) on each of the foundation layers and measuring a line width of the thick-film conductive patterns after printing and drying. FIG. 17 is a characteristic diagram of a pattern width of thick-film conductive patterns formed on a foundation layer that is formed on a substrate having thinner irregularities than 0.5 millimeter while changing thicknesses by a screen printing method while changing a mask size (an opening width size) from 0.05 millimeter to 0.10 millimeter after printing and drying. In FIG. 17, “without foundation” indicates a case of forming the conductive paste patterns directly on the substrate, a “foundation 1” indicates a case where the foundation layer is thin with respect to the irregularities on the substrate, a “foundation 2” indicates a case where the foundation layer has the standard thickness with respect to the irregularities on the substrate, and a “foundation 3” indicates a case where the foundation layer is thicker than the standard thickness with respect to the irregularities on the substrate. The foundation 1 corresponds to the foundation layer thickness of 0.002 millimeter to 0.005 millimeter in Table 2, the foundation 2 corresponds to the foundation layer thickness of 0.006 millimeter to 0.010 millimeter in Table 2, and the foundation 3 corresponds to the foundation layer thickness of 0.007 millimeter to 0.016 millimeter in Table 2.

Forming conditions for the thick-film paste patterns are similar to those in the case of FIGS. 8 to 16 except for the mask size (the opening width size). As for the line width of the thick-film patterns after printing and drying, both ends of each conductive paste pattern falling within a measurement window at a constant length (about 0.2 millimeter) were detected, and edges (left and right) of each pattern were measured from an average of the both ends (x coordinates). The line width of the thick-film pattern after printing and drying was defined as a distance between the two average points. This measurement operation was repeated 20 times in the length direction of the conductive pattern, thereby acquiring data.

It is understood from FIG. 17 that in the cases of without any foundation and the foundation 1, the pattern width of each conductive pattern after printing and drying was larger than that in the cases of the foundation 2 and the foundation 3, and that the effect of suppressing pattern smears was not obtained. That is, it was recognized even in the result of measuring the line width of each of the conductive paste patterns formed as described above that the effect of suppressing the pattern smears differed depending on the presence of the foundation layer and on the thickness of the foundation layer.

The conductive patterns were obtained by burning these conductive paste patterns at a burning temperature of 800° C. to 900° C. Because each of the foundation layers was made of the material that was burned down at the temperature higher than 500° C., the conductive-pattern-added substrate was able to be formed in such a manner that the conductive patterns were tightly and fixedly attached onto the substrate surface having irregularities after burning.

The pattern forming method according to the first embodiment described above is suited for forming grid electrodes of a solar battery having electrode patterns formed on a substrate having an irregular structure called “texture”. By using the pattern forming method according to the first embodiment, thick-film electrode patterns each at a small width while reducing an increase in the electrode pattern width can be formed. Therefore, an electrode part that cuts off incident light from sunlight can be formed to have a smaller area, and it is possible to suppress a reduction in power generation efficiency. The application of the pattern forming method according to the first embodiment is not limited thereto, and the method can be widely applied to cases of forming patterns on a substrate having irregularities on a surface thereof.

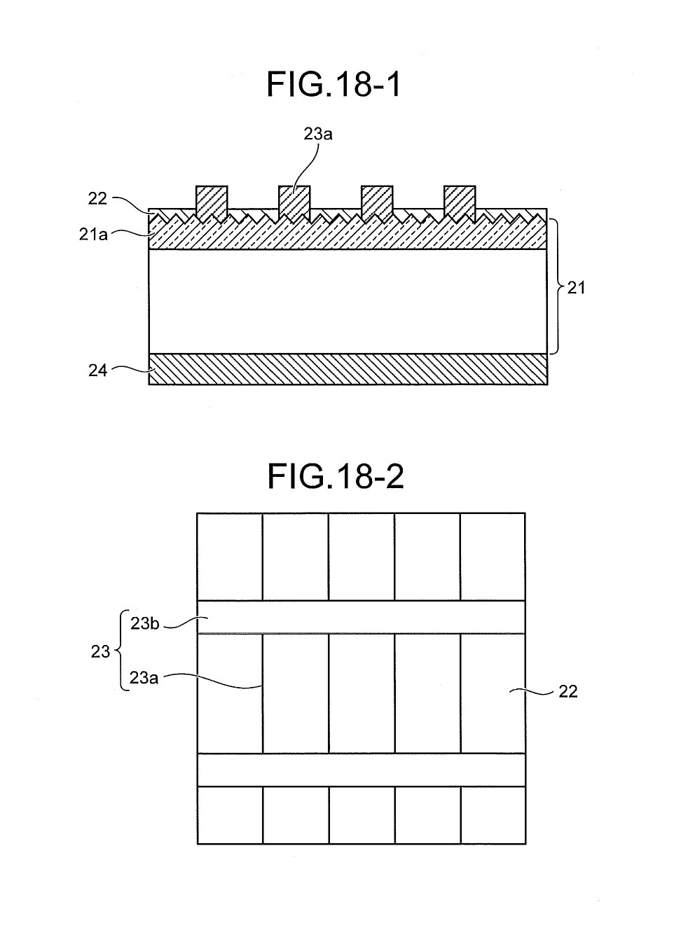

FIGS. 18-1 and 18-2 depict a solar battery, the electrode patterns of which are produced by the pattern formation method according to the first embodiment described above. FIG. 18-1 is a cross-sectional view of the solar battery and FIG. 18-2 is a top view of the solar battery. The solar battery shown in FIGS. 18-1 and 18-2 includes a P-semiconductor substrate 21 that is a semiconductor substrate of a first conductive type including an N-layer 21a that is an impurity diffusion layer having an impurity element of a second conductive type diffused to a substrate surface layer, an antireflection film 22 formed on a light-receiving surface (a front surface) of the semiconductor substrate 21, a light-receiving surface electrode 23 formed on the light-receiving surface (the front surface) of the semiconductor substrate 21, and a rear surface electrode 24 formed on a surface (a rear surface) opposite to the light-receiving surface of the semiconductor substrate 21. Alternatively, the solar battery can be configured to include a P-layer in an N-semiconductor substrate.

Furthermore, the light-receiving surface electrode 23 includes grid electrodes 23a and bus electrodes 23b. FIG. 18-2 depicts a cross-sectional view of a cross-section perpendicular to the grid electrodes 23a. The solar battery is configured to use a substrate having a texture structure formed on a substrate surface.

Steps of manufacturing the solar battery shown in FIGS. 18-1 and 18-2 are explained next. Because the processes explained below are similar to those of manufacturing a solar battery using a general polycrystalline silicon substrate, these processes are not specifically shown in the drawings.

First, as the semiconductor substrate 21, for example, a p-polycrystalline silicon substrate having a thickness of several hundreds of micrometers is prepared and washed. The p-polycrystalline silicon substrate is immersed in an acid solution such as a hydrofluoric acid solution or a heated alkaline solution and the surface of the substrate is etched. A damaged region generated at a time of cutting down the silicon substrate and present near the surface of the p-polycrystalline silicon substrate is thereby removed. The p-crystalline silicon substrate is then washed by pure water.

Subsequent to elimination of damage, the p-polycrystalline silicon substrate is immersed in a solution mixture of, for example, sodium hydroxide and isopropyl alcohol (IPA) to anisotropically etch the p-polycrystalline silicon substrate, and very small irregularities are formed on the light-receiving surface of the p-polycrystalline silicon substrate by a depth of about 10 micrometers, for example, thereby forming the texture structure. By providing such a texture structure on the light-receiving surface of the p-polycrystalline silicon substrate, multiple reflection of light occurs on a surface of the solar battery. It is thereby possible to efficiently absorb the light incident on the solar battery into the semiconductor substrate 21, and to effectively reduce reflectivity and improve conversion efficiency.

Next, the p-polycrystalline silicon substrate on which the texture structure is formed is input into a thermal oxidation furnace, and heated in the presence of phosphorous oxychloride (POCl₃) steam to form phosphorous glass on the surface of the p-polycrystalline silicon substrate, thereby diffusing phosphorus into the p-polycrystalline silicon substrate and forming the N-layer 21a on a surface layer of the p-polycrystalline silicon substrate. The semiconductor substrate 21 including the N-layer 21a on the surface layer thereof is thereby obtained.

After removing a phosphorus glass layer on the semiconductor substrate 21 in the hydrofluoric acid solution, an SiN film is formed on the N-layer 21a except for a region in which the light-receiving surface electrode 23 is formed as the antireflection film 22 by a plasma CVD method. A thickness and an index of refraction of the antireflection film 22 are set to values at which the antireflection film 22 can suppress light reflection most. Alternatively, two or more films having different indexes of refraction can be stacked. Furthermore, the antireflection film 22 can be formed by a different film forming method such as sputtering method.

Next, a silver-mixed paste is printed on the light receiving surface of the semiconductor substrate 21 into a coned shape by the screen printing. An aluminum-mixed paste is printed on the entire rear surface of the semiconductor substrate 21 by the screen printing. Thereafter, burning treatment is performed, thereby forming the light-receiving surface electrode 23 and the rear surface electrode 24. In order to form the light-receiving surface electrode 23, the pattern forming method according to the first embodiment described above is used. It is thereby possible to obtain the thick-film light-receiving surface electrode 23 having small smears. As described above, the solar battery shown in FIGS. 18-1 and 18-2 is produced.

### Second Embodiment

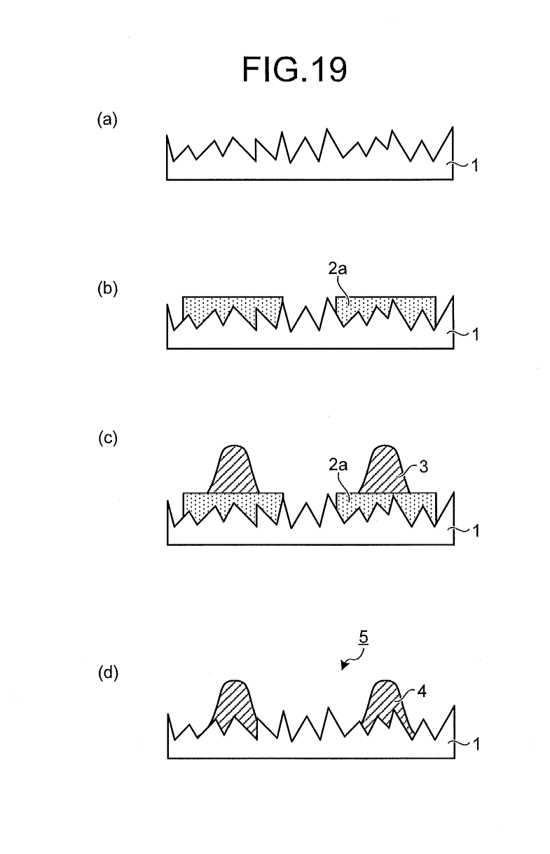

In a case of providing foundation layers on a substrate having irregularities on the surface thereof, the foundation layers can be formed into patterns having an increased width and an increased length from those of desired conductive patterns. FIG. 19 are cross-sectional views schematically depicting respective processes in a pattern forming method according to a second embodiment of the present invention. The pattern forming method according to the second embodiment differs from that according to the first embodiment in that a foundation-layer formation pattern is formed as patterns enlarged from conductive patterns. The pattern forming method according to the second embodiment is explained below with reference to FIG. 19.

First, the substrate 1 having irregularities on the surface is prepared and arranged while turning up the surface having the irregularities (FIG. 19(a)). Next, a foundation layer paste that becomes a foundation layer material is printed on an irregular surface of the substrate 1 by a screen printing method into patterns having an increased width and an increased length from those of conductive patterns, that is, into patterns obtained by expanding conductive-pattern formation regions. The printed foundation layer paste is dried, thereby forming foundation layers 2a (FIG. 19(b)).

The foundation layers 2a are formed in regions corresponding to conductive-pattern formation positions into the patterns having, for example, the line width increased by 0.05 millimeter to 0.1 millimeter from that of the conductive patterns on each side and having the length increased by 0.05 millimeter to 0.1 millimeter from that of the conductive patterns on each side. The foundation layer paste is a paste material containing the same binder components as those contained in a conductive paste that becomes the material of the conductive patterns to be printed in a next process.

Next, the conductive paste that becomes the material of the conductive patterns is printed on the foundation layers 2a by a screen printing method and the printed conductive paste is dried, thereby forming the conductive paste patterns 3 (FIG. 19(c)). The substrate 1 is burned under conditions of burning down the foundation layers 2a, the foundation layers 2a are burned down, and the conductive paste patterns 3 are burned. The burned conductive patterns 4 then contact the substrate 1 and are fixedly and tightly attached to the substrate 1, and the substrate 5 with conductive patterns is completed (FIG. 19(d)).

The pattern forming method according to the second embodiment described above is capable of making the foundation layer thick in combination with a reduction in a used amount of the foundation layer paste, effectively relaxing the irregularities on the substrate surface, and forming the conductive patterns of a stable shape without any increase in the formation width.

### Third Embodiment

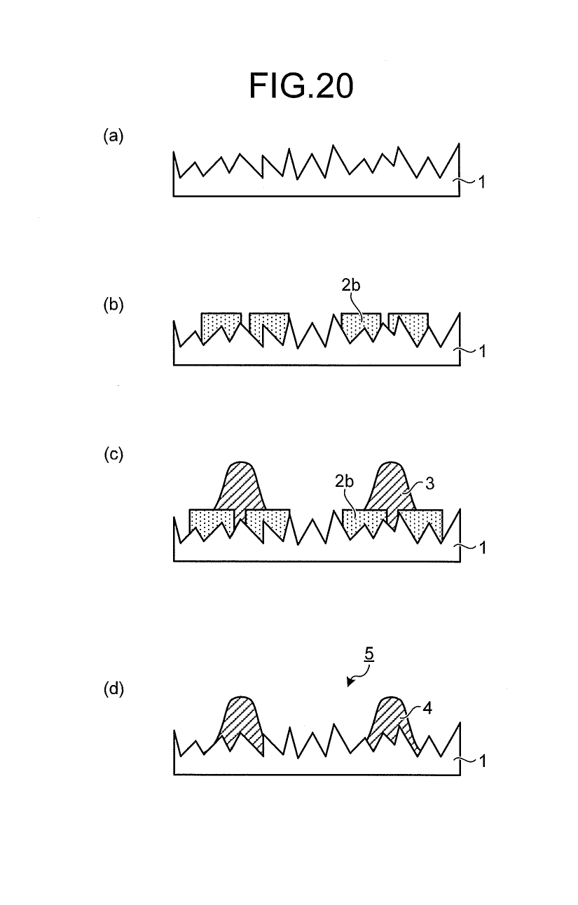

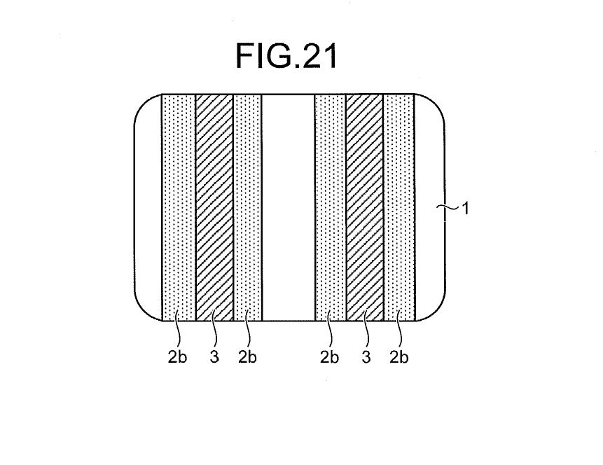

In a case of providing foundation layers on the substrate having irregularities on the surface thereof, the foundation layer can be formed in regions in which no conductive patterns are formed. FIG. 20 are cross-sectional views schematically depicting respective processes in a pattern forming method according to a third embodiment of the present invention. The pattern forming method according to the third embodiment differs from that according to the second embodiment in that foundation-layer formation patterns are formed as negative patterns of conductive patterns. That is, the foundation layers are formed near regions in which edges of the conductive patterns are formed in a width direction of the conductive patterns and not formed in a central region in the width direction of the conductive patterns. The pattern forming method according to the third embodiment is explained below with reference to FIG. 20.

First, the substrate 1 having irregularities on the surface is prepared and arranged while turning up the surface having the irregularities (FIG. 20(a)). Next, a foundation layer paste that becomes a foundation layer material is printed on the irregular surface of the substrate 1 by a screen printing method into negative patterns of conductive patterns. The printed foundation layer paste is dried, thereby forming foundation layers 2b (FIG. 20(b)).

For example, the foundation layers 2b are formed near the regions in which the edges of the conductive patterns are formed in the width direction of the conductive patterns and not formed in the central region in the width direction of the conductive pattern. In this case, the foundation layer paste is a paste material containing the same binder components as those contained in a conductive paste that becomes the material of the conductive patterns to be printed in a next process.

Next, the conductive paste that becomes the material of the conductive patterns is printed on the foundation layer 2b and in regions put between the foundation layers 2b by a screen printing method and the printed conductive paste is dried, thereby forming the conductive paste pattern 3 (FIG. 20(c)). FIG. 21 is a plan view of relevant parts schematically depicting a state where the foundation layers 2b and the conductive paste patterns 3 are formed on a surface of the substrate 1. The substrate 1 is burned under conditions of burning down the foundation layers 2b, the foundation layers 2b are burned down, and the conductive paste patterns 3 are burned. The burned conductive patterns 4 then contact the substrate 1 and are fixedly and tightly attached to the substrate 1, and the substrate 5 with conductive patterns is completed (FIG. 20(d)).

In the pattern forming method according to the third embodiment described above, the conductive paste patterns 3 directly contact the irregular surface of the substrate 1 at the time of printing, and pattern edges that cause smears contact the surfaces of the foundation layers 2b. Accordingly, it is possible to exhibit an effect of restricting an increase in the conductive patterns by the surface roughness of the foundation layers 2b, and to form the conductive patterns of a stable shape without any increase in the formation width.

### INDUSTRIAL APPLICABILITY

As described above, the pattern forming method according to the present invention is useful in a case of forming patterns on a thin substrate having irregularities on a surface in a stable state with fewer pattern smears.

### REFERENCE SIGNS LIST

1 substrate
2 foundation layer
2a foundation layer
2b foundation layer
3 conductive paste pattern
4 conductive pattern
5 substrate with conductive patterns
21 semiconductor substrate
21a N-layer
22 antireflection film
23 light-receiving surface electrode
23a grid electrode
23b bus electrode
24 rear surface electrode

1. A pattern forming method of forming a pattern by printing a pattern formation paste containing a pattern forming material and a binder component on a substrate having irregularities on a surface by a screen printing method, the pattern forming method comprising:
a foundation-layer forming step of forming a foundation layer by printing a foundation layer paste containing a same binder component as the binder component contained in the pattern formation paste on the surface of the substrate by the screen printing method in such a manner as to cover the irregularities with the foundation layer paste;
a paste-pattern forming step of forming a pattern of the pattern formation paste by printing the pattern formation paste on the foundation layer by the screen printing method; and
a burning step of burning the pattern of the pattern formation paste and burning down the foundation layer, thereby forming a pattern in contact with the surface of the substrate.

2. The pattern forming method according to claim 1, wherein the binder component is a resin and a solvent.

3. The pattern forming method according to claim 1, wherein the foundation layer is formed partially on the surface of the substrate into a pattern having an expanded printing region from a printing region of the pattern of the pattern formation paste.

4. The pattern forming method according to claim 3, wherein the foundation layer is formed into a negative pattern of the pattern of the pattern formation paste.

5. (canceled)

6. A manufacturing method of a solar battery comprising:
an irregular-shape forming step of forming an irregular shape on one surface side of a semiconductor substrate of a first conductive type;
an impurity-diffusion-layer forming step of forming an impurity diffusion layer into which an impurity element of a second conductive type is diffused on the one surface side of the semiconductor substrate on which the irregular shape is formed; and
an electrode forming step of forming an electrode pattern on the surface of the semiconductor substrate by a pattern forming method of forming a pattern by printing a pattern formation paste containing a pattern forming material and a binder component on a substrate having irregularities on a surface by a screen printing method, including:
a foundation-layer forming step of forming a foundation layer by printing a foundation layer paste containing a same binder component as the binder component contained in the pattern formation paste on the surface of the substrate by the screen printing method in such a manner as to cover the irregularities with the foundation layer paste;
a paste-pattern forming step of forming a pattern of the pattern formation paste by printing the pattern formation paste on the foundation layer by the screen printing method; and
a burning step of burning the pattern of the pattern formation paste and burning down the foundation layer, thereby forming a pattern in contact with the surface of the substrate.
